(19) United States
(12) Patent Application Publication
(10) Pub. No.: US 2009/0160009 A1
(43) Pub. Date: Jun. 25, 2009

(54) Semiconductor array and method for manufacturing a semiconductor array

(75) Inventors: Franz Dietz, Untereisesheim (DE); Volker Dudek, Ettlingen (DE); Tobias Florian, Stuttgart (DE); Holger Hoehnemann, Leingarten (DE); Stefan Schwantes, Heilbronn (DE)

Correspondence Address: Muncy, Geissler, Olds & Lowe, PLLC, P.O. BOX 1364, FAIRFAX, VA, 22038-1364, US

(73) Assignee: ATMEL Germany GmbH, Heilbronn (DE)

(21) Appl. No.: 11/528,399

(22) Filed: Sep. 28, 2006

(30) Foreign Application Priority Data
Sep. 29, 2005 (DE) 10 2005 046 624.9

(51) Int. Cl. H01L 23/58; H01L 21/762

(52) U.S. Cl. 257/506; 438/424; 257/E21.546

(57) ABSTRACT

Semiconductor array and method for manufacturing a semiconductor array, wherein
a conductive substrate (100), an element region (400), and an insulation layer (200), isolating the element region (400) from the conductive substrate (100), are formed,
a trench (700) is etched in the element region (400) as far as the insulation layer (200),
the trench (700) is etched further in the insulation layer (200) as far as the conductive substrate (100), and
within the trench (700), the conductive substrate (100) is at least partially etched to form conductive substrate regions (141, 142, 143, 144, 145, 146), isolated from one another.

The present invention relates to a semiconductor array, a use, a circuit, and a method for manufacturing a semiconductor array.

A method for manufacturing a semiconductor element is known from German Patent DE 102 60 616 B3. In this case, an element structure is formed on a wafer, whereby the wafer comprises a backside semiconductor substrate, a buried isolation layer, and a top semiconductor layer. An etch stop layer is formed on the wafer. The wafer carries the element structure. A window is formed in the etch stop layer. A dielectric layer is formed on the etch stop layer, which has a window formed therein. This is followed by simultaneous etching of a first contact hole through the dielectric layer and the window down to the backside semiconductor substrate and at least one second contact hole through the dielectric layer down to the element structure.

In the manufacturing of semiconductor elements, SOI wafers or substrates are used to provide superior isolation between adjacent elements in an integrated circuit as compared to elements built into bulk wafers. SOI substrates are silicon wafers with a thin layer of oxide or other insulators buried therein. Elements are built into a thin layer of silicon on top of the buried oxide. The superior isolation thus achieved may eliminate the “latch-up” in CMOS elements (CMOS: Complementary Metal Oxide Semiconductor) and further reduces parasitic capacitances. In addition to the buried oxide layer, shallow trench isolation (STI) is often used to completely isolate transistors or other elements from each other.

Because the backside silicon substrate is completely decoupled from the elements by means of the buried oxide, the potential of the backside substrate tends to float during the operation of the circuit. This may influence the properties of the circuit and reduce operation reliability.

To prevent the backside silicon substrate of the element from floating, special contacts are formed to connect the backside substrate to a metal layer that has a defined potential. An SOI structure is used first that comprises a backside silicon substrate, a buried oxide layer, and a top silicon layer. Transistor structures are formed on top of the SOI structure. The top silicon layer has etched isolation trenches, filled with STI material, to decouple the transistor structures from each other and from other elements.

On top of the top silicon layer, the STI material of the isolation trenches, and the transistor structures, for example, a silicon oxynitride (SiON) layer is deposited that is used in subsequent etching processes as a stop layer. Further, suicides may be formed between this etch stop layer and the top silicon layer.

Further, a TEOS (tetraethylorthosilicate) layer is deposited as a masking layer. Then, after the transistor structures and the contact stack of silicon oxynitride (SiON) and tetraethylorthosilicate (TEOS) are formed, a photoresist layer is patterned to provide a backside contact mask having an opening for etching a contact to the backside silicon substrate.

Once the backside contact mask pattern is defined in the photoresist layer, the stack of tetraethylorthosilicate (TEOS), silicon oxynitride (SiON), STI material, and buried oxide is etched down to the backside silicon substrate. A contact hole is formed by this etching step. The STI material of the isolation trench is divided by the formation of the contact hole. The photoresist is now removed by a plasma strip and an additional wet chemical cleaning step.

Once the backside contact hole has been formed, the formation of contacts to connect the transistor structures takes place. This will require another photoresist layer patterning process and a separate etching step.

The aforementioned prior art can be derived, for example, from Unexamined German Patent Application DE 100 54 109 A1. In addition, reference is made to U.S. Pat. No. 5,965,917 A, which also deals with the problems of substrate contacting in SOI structures. Two conductive substrate layers, isolated from one another by a buried oxide layer, as conductive rails, each of which are contacted by a deep trench, are known from U.S. Patent Application No. 2003/0094654 A1.

A through-hole plating through a buried insulation layer in a semiconductor substrate is known from European Patent EP 1 120 835 A2. In this case, the through-hole plating connects the source region of a field effect transistor with the semiconductor substrate formed under the buried insulation layer. A method for producing substrate contacts in SOI circuit structures is also known from German Patent DE 103 03 643 B3. In this case, several layer sequences of overlapping metallization layers are formed in the area of the contacting. On the other hand, a contacting of a silicon substrate in a doped region by means of polysilicon is disclosed in WO 02/073667 A2.

Contacting of a substrate region through a dielectric layer is known from U.S. Pat. No. 6,372,562 B1, whereby the contacted substrate region is isolated from another substrate region by a p-n junction poled in the blocking direction. The U.K. Patent Application No. GB 2 346 260 A also discloses a method for forming a contact to a substrate region isolated by a p-n junction in a deep trench of an SOI component. A method for producing a trench in a substrate and its use in smart power technology is known from EP 0 635 884 A1. In this case, after reinforcing a trench mask by means of a non-conformally deposited protective layer, the buried insulation layer is etched as far as the silicon substrate in a second trench etching. Another method for producing substrate contacting is known from U.S. Pat. No. 6,632,710 B2.

The invention has as its first object the further development of a method for producing a contacting of a substrate with as improved a process reliability as possible.

This object is achieved by the method with the features of claim 1. Advantageous development variants are the subject of dependent claims.

Accordingly, a method for manufacturing a semiconductor array is provided. The method has several process steps. In this case, a conductive substrate, an element region, and an insulation layer isolating the element region from the conductive substrate are formed. This type of structure is also called an SOI structure (Silicon-On-Insulator). To produce an SOI structure of this type, a first wafer is preferably bonded to the element region and the insulation layer on a second wafer to the conductive substrate, so that in regard to the wafer surface the elements are formed adjacently topmost on the insulation layer and the insulation layer adjacently above the conductive substrate. The element region preferably has a single-crystal semiconductor to form the semiconductor elements. A suitable semiconductor material is, for example, silicon, germanium, or mixed crystals, such as gallium arsenide.

In another process step, a trench is etched substantially in the vertical direction in the element region as far as the insulation layer. Reactive ion etching (ICP, Inductive Coupled Plasma) may be used, for example, for the etching. Preferably, the etching is thereby selective for the semiconductor material of the element region. This etching stops thereby at the interface to the insulation layer. Preferably, the trench has a high depth-to-width aspect ratio.

In a later process step, the trench is etched further in the insulation layer as far as the conductive substrate. Preferably, the etching is thereby selective for the dielectric of the insulation layer. This etching thereby stops at the interface to the conductive substrate.

It is provided according to the invention that the conductive substrate is etched partially to form conductive substrate regions, isolated from one another. The etching of the conductive substrate causes a patterning with substrate regions separated from one another. In fact it is possible in principle to use this separation as isolation, but it is preferably provided that a dielectric is formed for isolation. The patterning in conductive substrate regions, separated from one another, thus occurs after the bonding of the wafer. Preferably, an oxide covering the bottom of the trench is removed before the etching of the conductive substrate.

In a preferred and especially advantageous development, it is provided that the conductive substrate is etched at least partially within the trench in order to form the substrate regions, isolated from one another. The etching therefore occurs on the same wafer side as the etching of the trench, within an opening formed by the trench. The etching is thereby preferably selective for the conductive substrate material to be etched. Said material to be etched is preferably formed as a conductive substrate layer.

According to an advantageous development variant, first a conductive layer of the substrate is patterned by etching to form the isolation of the substrate regions. In a later process step, in this development variant an exposed region of the conductive layer is thermally oxidized to form an insulating dielectric. Preferably, the conductive layer therefore has silicon for thermal oxidation.

Another advantageous development provides that for patterning, a mask is formed which protects a first region of the conductive layer within the trench from the etching attack. However, a second region, not protected by the mask, of the conductive layer is removed by the etching. After removal of the mask, therefore, a portion of a conductive substrate region remains within the trench. For example, a photolithographically patterned photoresist can be used for masking.

Alternatively to or in combination with thermal oxidation of the exposed region of the conductive layer, according to another development variant, a dielectric is deposited within the trench between the formed substrate regions. This dielectric is, for example, silicon nitride or preferably silicon dioxide. To form the isolation of the substrate regions, a conductive layer of the substrate within the trench is removed beforehand at least partially by etching, so that a separation trench forms as a gap between the conductive substrate regions. It is preferably provided that the trench is at least partially filled with the dielectric at the same time with the same filling of the gap between the conductive substrate regions.

According to another development variant, it is provided that preferably after the etching steps an electrical conductor is introduced in the trench isolated by the insulation material from the semiconductor material of the element region or into another trench and conductively connected to a substrate region of the substrate regions, isolated from one another.

It is provided advantageously that the substrate is formed with a dielectric layer and with a conductive layer. For this purpose, for example, doped, particularly polycrystalline silicon is applied to a silicon dioxide wafer. It is also possible to bond a single-crystal silicon wafer with a silicon dioxide wafer and to polish the thickness of the single-crystal silicon layer to a thickness of a few micrometers.

In a process step of an advantageous development variant, a shallow recess is etched in a surface of the element region. The etching occurs preferably with a small depth-to-width aspect ratio for the etched recess (STI). In a later process step, within the shallow recess, the trench is etched in the element region as far as the insulation layer through the semiconductor material of the element region. In this case, the etching occurs preferably selectively in regard to oxide layers. Furthermore, for etching the trench, it is preferable to use an etching that enables a high depth-to-width aspect ratio for the etching (Deep Trench).

The walls of the trench are formed next with an insulation material. To form the insulation material, for example, an oxide can be deposited on the wall regions of the trench. Preferably, to form the insulation material, however, a silicon material, adjacent to the trench, of the element region is oxidized. Preferably, in this case, the insulation material is adjacent to the buried insulation layer.

According to a preferred development of the invention, it is provided that the shallow recess is filled with dielectric. After the filling with dielectric, a dopant, for example, boron, is introduced for a semiconductor region of the at least one element. For introduction, the dopant can be diffused in and/or implanted, for example. The dielectric in the shallow recess thereby serves as masking to make the semiconductor region of the at least one element self-aligned to the recess in the element region. For self-aligning, the dielectric has, for example, such a thickness that during introduction of the dopant, it is introduced exclusively next to the dielectric in the element region. However, substantially no introduction of the dopant occurs in a region in the vicinity of the deep trench below the dielectric in the shallow recess. A semiconductor region, formed by the introduced dopant and assigned to the at least one element in the element region, is thereby positioned next to the shallow recess. Moreover, no additional mask edge is necessary, so that this can be called self-aligning.

In an advantageous further development of the invention, it is provided that a number of elements in the element region are formed after the formation of the insulation material to insulate the trench walls. The thermal budget for forming the elements in the element region can therefore occur independent of the formation of the deep trenches. If a polysilicon conductor is introduced into the deep trench, this can also occur advantageously before the formation of the semiconductor elements. The majority of the elements are thereby isolated from one or more substrate regions in the vertical direction by the buried insulator layer. Furthermore, the insulation material in the deep trenches and the insulation material in the shallow recess make possible a lateral isolation of at least two elements. Preferably to improve the invention further, an isolation trench is etched concurrently with the etching of the trench for receiving the conductor, whereby the isolation trench is completely filled with an insulator and serves exclusively to isolate an element.

Another variant provides that the conductive substrate to form conductive substrate regions, isolated from one another, is etched from the substrate side facing away from the trench. This etching can also occur additionally after the formation of the element. For contacting a substrate region from the side of the element, an electrical conductor is introduced into the trench and conductively connected to at least one substrate region of the conductive substrate regions. In so doing, the walls of the trench are formed with an insulation material.

A second object forming the basis of the invention is to provide a semiconductor array. This object is achieved by the semiconductor array with the features of claim 12. Advantageous development variants are the subject of dependent claims.

Therefore, a semiconductor array is provided. Said semiconductor array has an element region, a conductive substrate, and a buried insulation layer, whereby the insulation layer isolates the element region from the conductive substrate. In regard to the wafer surface, the buried insulation layer is thereby preferably applied on top of the substrate and the element region on top of the buried insulation layer, in an adjacent manner in each case. This type of array with a buried insulation layer with use of silicon as the semiconductor material is also called SOI (Silicon On Isolator). The buried insulation layer may have, for example, silicon dioxide.

The semiconductor array has at least one trench filled with an insulation material. This trench isolates at least one element in the element region from other elements in the element region. Elements, such as field-effect transistors, are formed in the element region. For this purpose, the element region is formed from a single-crystal semiconductor material, advantageously from silicon with preferably a <100> crystal orientation.

An electrical conductor is conductively connected to the conductive substrate. The electrical conductor is isolated by the insulation material filling the trench and disposed within the trench. The trench is thereby formed as far as a surface. Consequently, the trench is adjacent to the element region.

The substrate has conductive substrate regions, which are divided by etched separation trenches. A dielectric, which isolates the substrate regions from one another, is formed in the separation trenches. Preferably, the substrate regions are formed in one layer and in addition, are only spaced apart laterally. In order to bring about the conductivity, the substrate regions are preferably of doped semiconductor material, such as, for example, silicon or mixed crystals such as silicon germanium or silicon carbide. In this case, the doped semiconductor material may be single-crystal or amorphous, but preferably polycrystalline. The conductivity type of the dopants is advantageously matched to the conductivity type of the contacting semiconductor material. Different conductivity types can also be provided for different substrate regions.

The conductive substrate therefore has a number of substrate regions isolated from one another. These substrate regions may be separated from one another, for example, by deep trench etching for the separation trenches. Preferably, these deep separation trenches are then filled with a dielectric. A separate, fixed or variable potential can thereby be applied to each substrate region independently from one another, so that separate elements in the element region can be operated with different applied substrate potentials.

The contacting of the conductive substrate can thereby be used for different functions. An important function is to change the element parameters of elements disposed on the opposite side of the buried insulation layer by the amount or the time course of the applied substrate potential. In particular, the breakdown voltage of a lateral N-DMOS transistor or a P-DMOS transistor can be improved. Furthermore, a current gain of an NPN-bipolar transistor can be changed, particularly increased, by the amount of an applied substrate potential. It is possible to achieve considerable improvement for positive substrate potentials in this way. Furthermore, the substrate may be used in addition as a line connection to another element or to an integrated circuit contact disposed on the backside. It is also possible by introducing dopants into the substrate, to form semiconductor elements, such as, for example, diodes in the substrate.

According to an advantageous development variant, it is provided that several substrate regions, isolated from one another, are each conductively connected to at least one conductor each disposed in a trench. This development variant is preferably used for elements, whose electrical properties can be influenced by an electrode formed by the substrate region made in each case below the element. Thus, by means of a first substrate region, connected in this manner, below an N-LDMOS field-effect transistor, the electrical properties of the latter can be controlled by application of a potential. However, a P-LDMOS field-effect transistor with a second substrate region, which is isolated from the first substrate region and connected separately, is controlled independently by another potential in its electrical properties. In addition, a non-contacted substrate region may also be provided.

In another advantageous development variant, at least one of the substrate regions is formed below the element. Preferably, the element is a lateral DMOS field-effect transistor.

According to an again different development variant, it is provided that the conductor and one substrate region of the substrate regions surround the at least one element at least partially or a circuit with the at least one element and are together formed as screening. Preferably, the at least one element or the circuit is isolated in addition by the dielectric on all sides except for the terminals, whereby the screening preferably surrounds the insulating dielectric.

In an advantageous development variant, it is provided that a dielectric is introduced within the trench. This dielectric is introduced in a gap formed by a separation trench between the substrate regions and isolates the substrate regions from one another. For introducing the dielectric, it can be, for example, sputtered in or deposited by means of CVD.

According to an advantageous development variant, the trench is formed within a recess in the surface. The recess in the surface is preferably shallower than the depth of the trench. Furthermore, the recess in the surface is preferably wider than the width of the trench. It is especially preferred for the recess in the surface to have a smaller aspect ratio than the trench. The aspect ratio here is the ratio of the depth of the trench or the recess to its width. The surface is preferably the surface facing away from the substrate of the element region of the semiconductor array.

According to a preferred embodiment variant, it is provided that the trench is formed not in an edge region of the recess, but in a central area, preferably in the center of the recess. In fact, it is possible to produce the recess in the surface by a local oxidation (LOCOS; LOCal Oxidation of Silicon), but preferably small structures are made. For this purpose, a development of the invention provides that a shallow trench is provided as the recess. Said shallow trench is preferably filled with dielectric. This is also called STI (Shallow Trench Isolation). Within this shallow trench (STI), the deep trench (Deep Trench Isolation) is formed with a higher aspect ratio. Preferably, both trenches are etched in the semiconductor material of the element region.

According to another advantageous development, a semiconductor region of the at least one element is formed self-aligned to the recess in the element region. The semiconductor region is, for example, a diffused well with one dopant type. Preferably, the semiconductor region is a semiconductor terminal region formed, for example, by implantation of a dopant. Due to the self-alignment, the semiconductor region is adjacent to the recess.

Advantageous embodiments of the invention provide that the electrical conductor has a highly doped semiconductor material and/or metal and/or silicide.

Another aspect of the invention is a circuit with an aforementioned semiconductor array. This circuit preferably has a lateral DMOS field-effect transistor. The circuit has means for applying a constant or controllable potential to the electrical conductor. In this case, at least one electrical property of the element depends on the constant or controllable potential. This type of means is, for example, a connection to a supply potential or a connected potential shifter.

Another unique aspect of the invention is a use of a conductive substrate region and a conductor, connected conductively to the substrate region, for multisided screening of a number of elements. In this case, at least one element is provided. This is disposed on top of the conductive substrate region and isolated dielectrically from the substrate region. This aspect of the invention can be combined with the previously explained development variants.

The previously described development variants, embodiment variants, and aspects of the invention are especially advantageous both individually and in combination. In this regard, all development variants, embodiment variants, and aspects of the invention can be used in combination with one another. Possible combinations are explained in the description of the exemplary embodiments in the figures. These possible combinations, described therein, of development variants, embodiment variants, and aspects of the invention are not definitive, however.

In the following text, the invention will be illustrated in greater detail in exemplary embodiments using the drawings with FIGS. 1 through 17.

Here, the figures show:

FIG. 1 to FIG. 8 schematic sectional views through a wafer at different process time points in the manufacture of a semiconductor array of the first exemplary embodiment;

FIG. 9 a schematic sectional view of an LDMOS field-effect transistor of the first exemplary embodiment with a connection to the substrate;

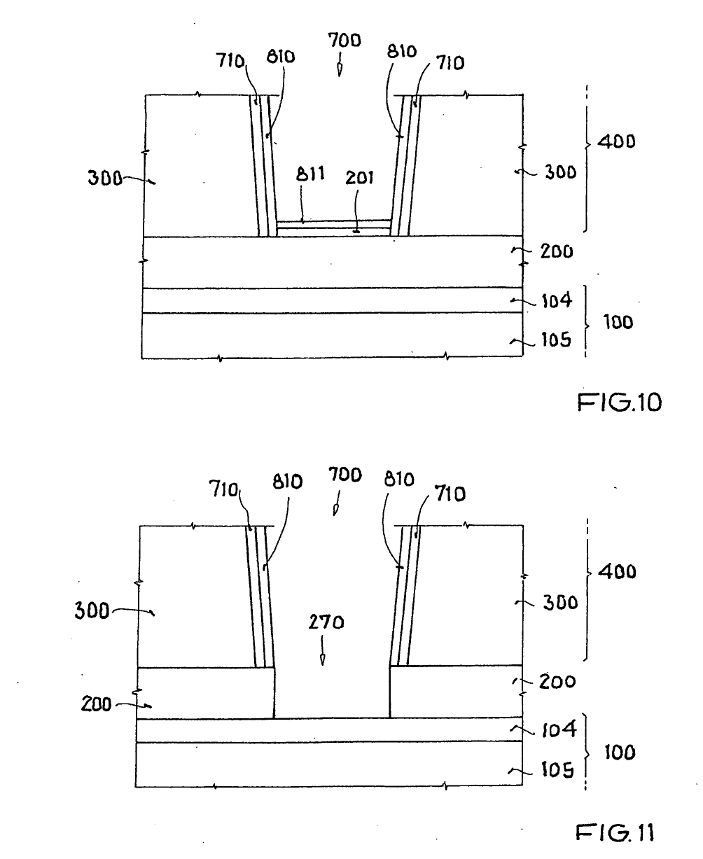

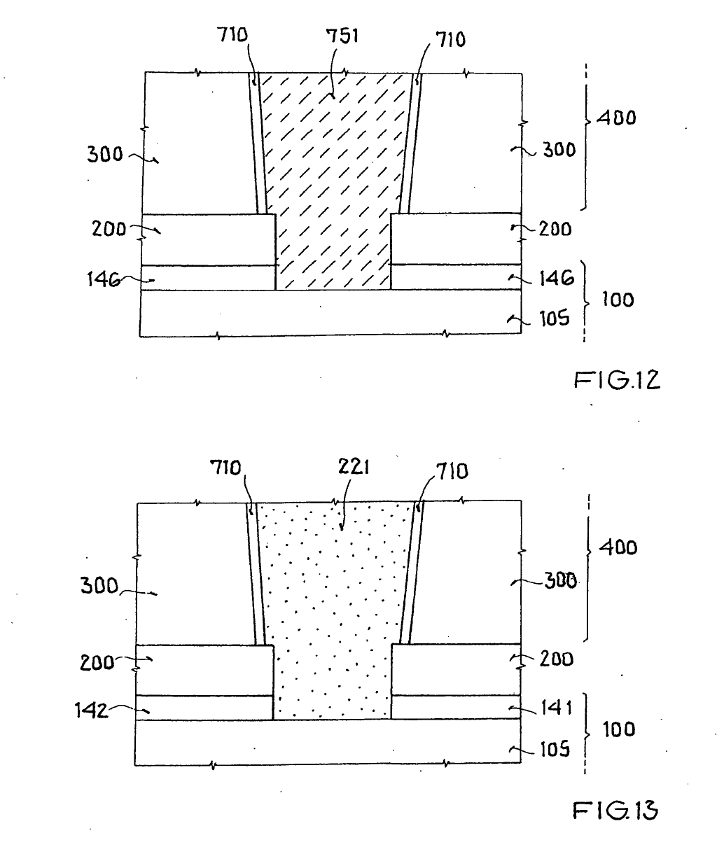

FIG. 10 and FIG. 11 schematic detailed sectional views of another exemplary embodiment at different process time points;

FIG. 12 a schematic detailed sectional view of a trench filled with polycrystalline silicon at a process time point;

FIG. 13 a schematic detailed sectional view of a trench filled with silicon dioxide at a process time point;

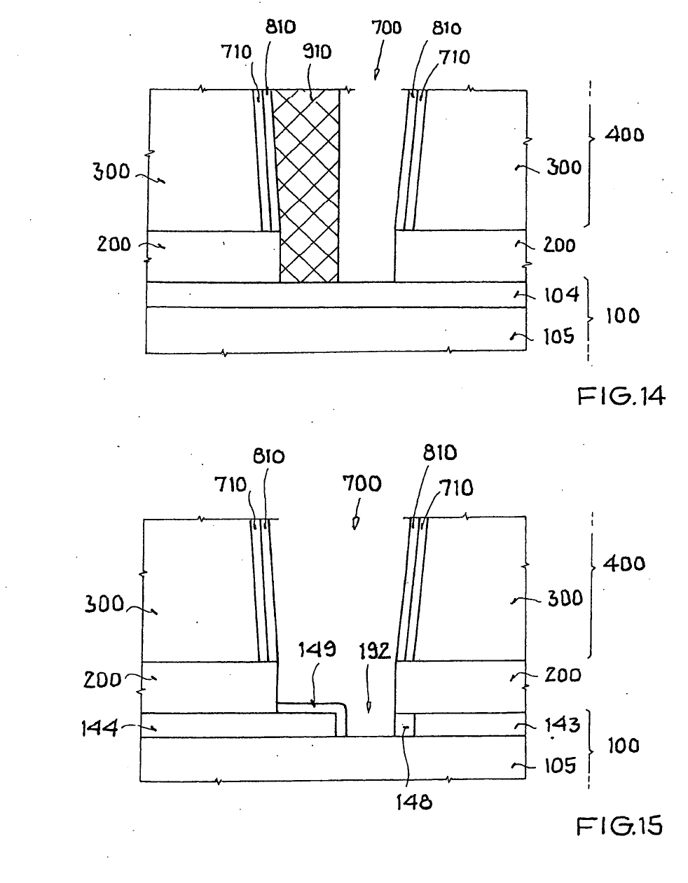

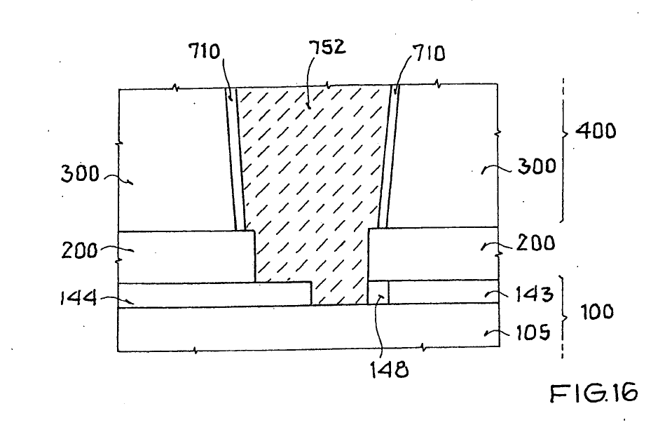

FIG. 14 to FIG. 16 schematic detailed sectional views of another exemplary embodiment at different process time points; and

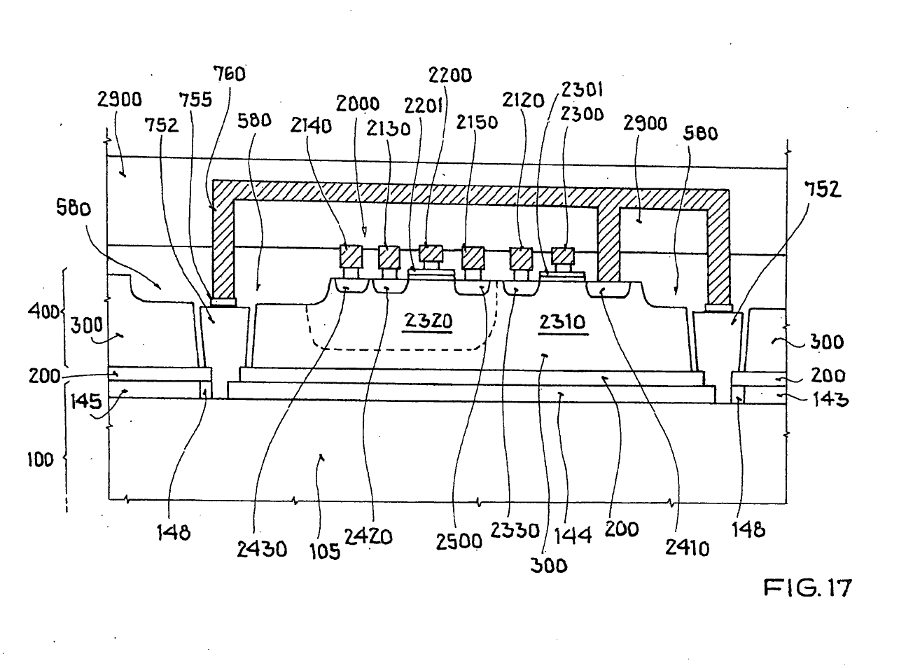

FIG. 17 a schematic sectional view of a semiconductor array with an LDMOS field-effect transistor.

Schematic sectional views through a wafer at different process time points in the manufacture of a semiconductor array are shown in FIGS. 1 through 17. The same structural elements are usually provided with the same reference characters. In the following text, as a result, only the most important process steps are described for the sake of easier understandability. In this case, other process steps, typical in semiconductor fabrication and known per se to the person skilled in the art, such as deposition, cleaning steps, and planarization, are not explained further. These can be utilized in order to integrate the method into an overall production process.

An element region 400 of a semiconductor material, in this case silicon 300, a conductive, n-doped silicon substrate 100, and a buried insulation layer 200 are shown in FIG. 1. Insulation layer 200 isolates element region 400 from silicon substrate 100. Insulation layer 200 is a dielectric, for example, of silicon dioxide (SiO₂). A hard mask 800 of silicon nitride (Si₃N₄) is applied to silicon 300 of element region 400 for masking. A recess 600 is etched in the form of a shallow trench 600 (STI) into the surface of element region 400 made of silicon 300, whereby regions for forming elements are protected by hard mask 800 from the etching attack.

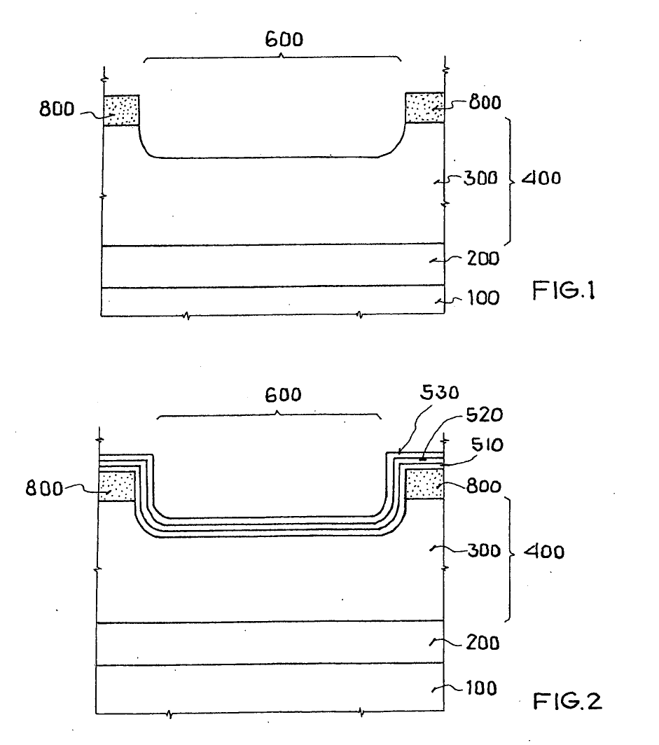

In FIG. 2, a layer sequence comprising a first silicon dioxide layer 510 (SiO₂), a layer of polycrystalline silicon 520 (poly-Si), and a second silicon dioxide layer 530 (SiO₂) is applied within the etched shallow trench 600 and on hard mask 800. This layer sequence 510, 520, 530 is also called an OPO layer. Preferably, these layers 510, 520, 530 are deposited successively one after another.

The layer sequence of layers 510, 520, 530 is patterned lithographically by a photoresist and a mask in such a way that a vertical opening is introduced into the layer sequence. A deep trench 700 (Deep Trench) is etched through this vertical opening. This etching is selective in regard to second oxide layer 530 and thereby substantially removes only silicon 300. After this, buried oxide 200 is removed below the etched opening. At the same time, second oxide layer 530 is also removed. FIG. 3 shows the state after etching of buried oxide 200 below the etched opening and the second oxide layer. Deep trench 700 has trench walls 701 and a trench bottom 702.

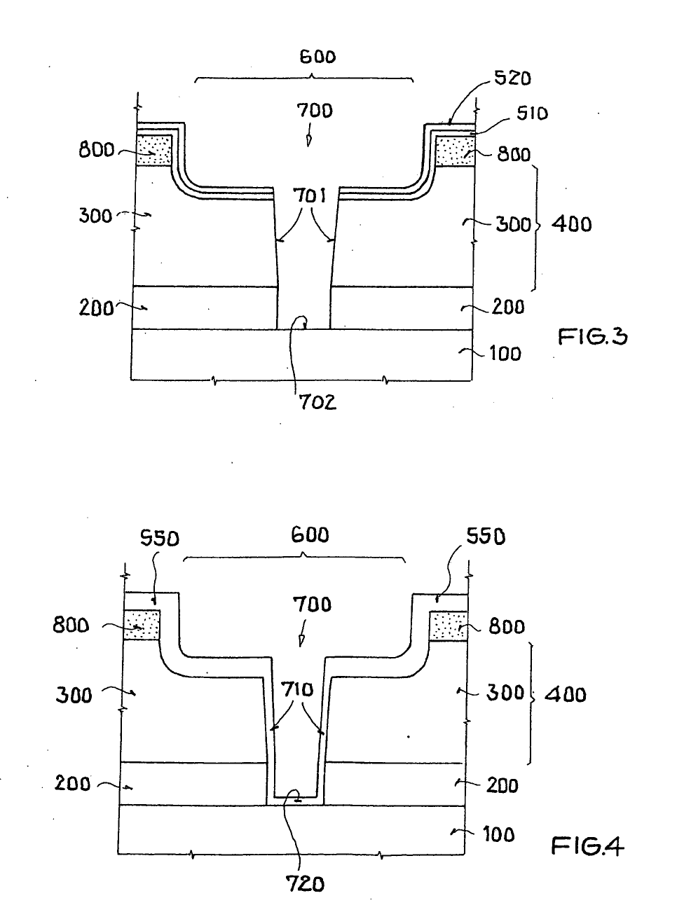

Subsequently, in the next process step, a thermal oxide of the highest quality possible is produced, preferably with a thickness of 50 nm. In this case, an oxide layer 710 or 720, respectively, is formed at trench walls 701 and on trench bottom 702. This state is shown schematically in FIG. 4. In this case, the silicon material of element region 400 in the wall region and the silicon material of silicon substrate 100 are converted to silicon dioxide. Furthermore, polysilicon layer 520 is also converted to silicon dioxide, so that together with first oxide layer 510, a thicker silicon dioxide top layer 550 is formed at least within shallow recess 600 on element region 400.

In the next process step, oxide 720 on the bottom of deep trench 700 is etched off by anisotropic etching. This process state is shown in FIG. 5. In this case, the silicon dioxide top layer 550′ is accordingly thinned, but not totally removed.

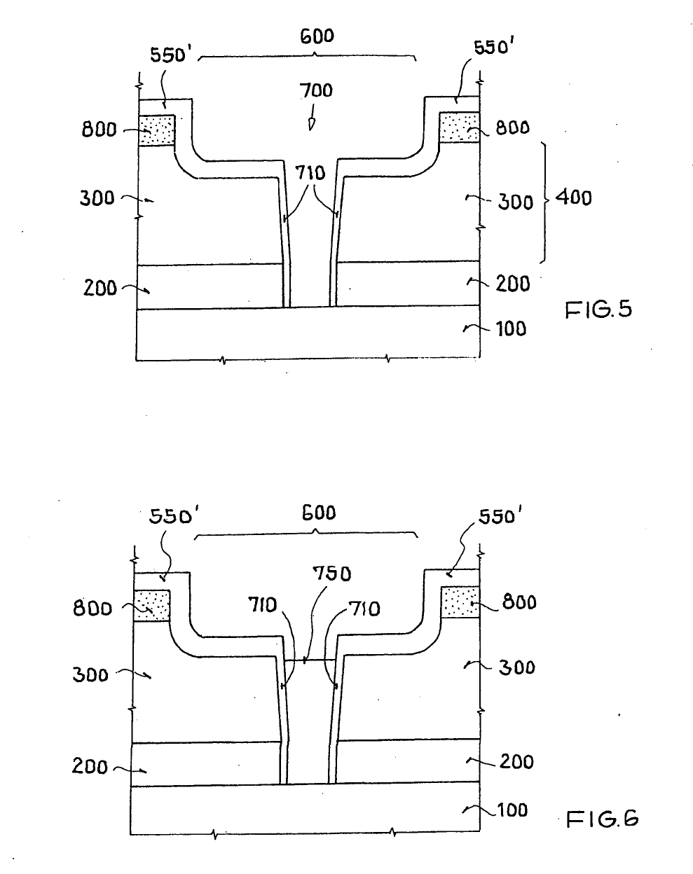

Then, conformal polysilicon 750 or amorphous silicon 750 is deposited on the wafer and etched back to the entrance of deep trench 700. This state is shown in FIG. 6. Polysilicon 750 can either be already doped during the deposition or in the later contact opening by implantation. The doping type advantageously corresponds to that of silicon substrate 100.

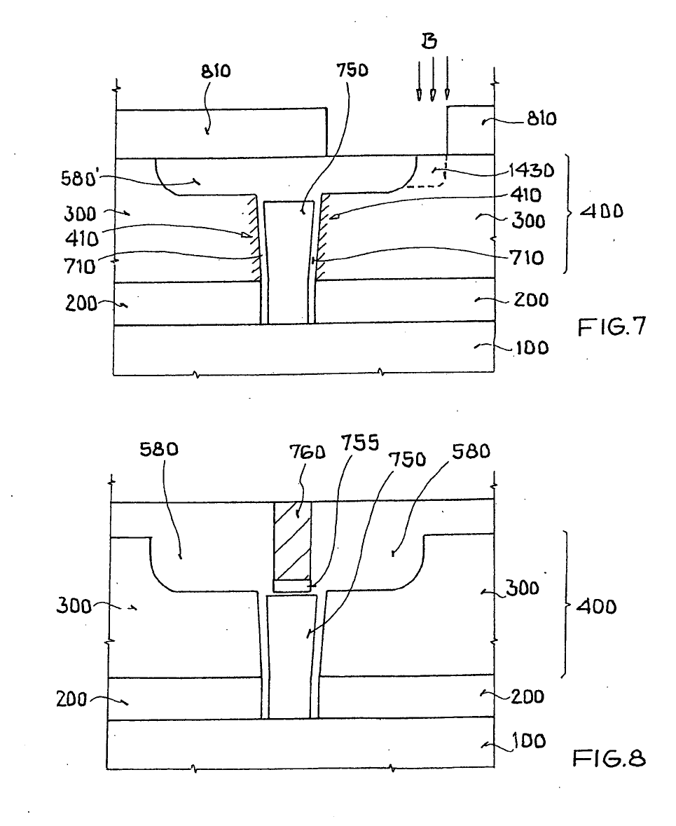

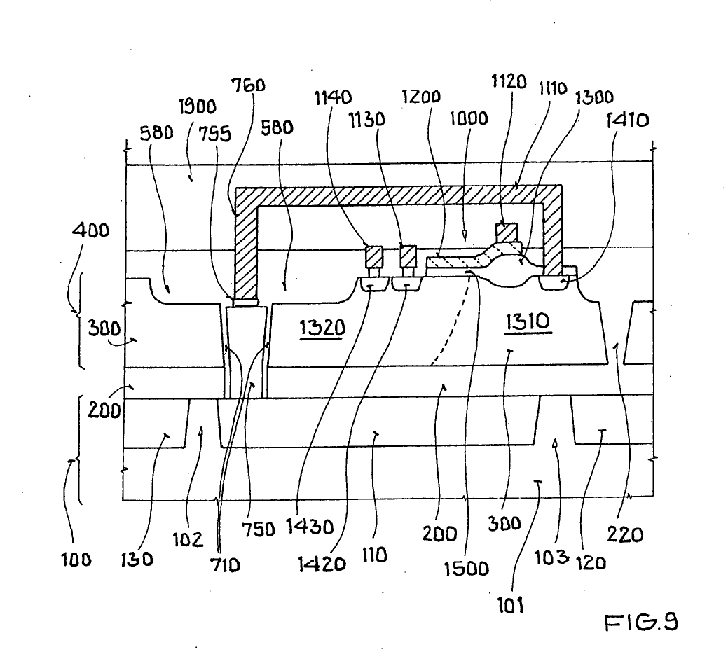

Next, to achieve the process state according to FIG. 7, shallow trench 600 is filled with oxide 580′, the hard mask (800) is removed, and the wafer surface is planarized, for example, by means of chemical mechanical polishing (CMP). The next process steps are used to produce the semiconductor elements in element region 400. In this case, a resist 900 is applied and patterned photolithographically as implantation mask 900. In so doing, oxide 580′ in shallow trench 600 also forms a mask, which protects semiconductor material 300 of element region 400 in the area below oxide 580′ from the dopant to be implanted.

The masking by oxide 580′ has the effect that a semiconductor region 1430 of an associated element 1000 (see FIG. 9) is formed adjacent to oxide 580′ in shallow trench 600. Semiconductor region 1430 is, in addition, oriented by the masking self-aligning to shallow trench 600. In the exemplary embodiment of FIG. 7, boron B is implanted as the dopant, whereby semiconductor region 1430, for example, is formed as a p-doped semiconductor terminal region with a high dopant concentration.

In an area of element region 400, which is laterally adjacent to shallow trench 600, the density of the crystal defects in the element region is much lower than in a border area 410 of element region 400, which is laterally adjacent to deep trench 700. Border area 410, adjacent to oxide 710, of element region 400 can have a high density of imperfections in the single-crystal crystal lattice. The arrangement of the deep trench within the shallow trench by the self-aligning of semiconductor region 1430 and thereby by the self-aligning of element 1000 makes possible a guaranteed distance between the deep trench and active regions of element 1000, so that process variations can be reduced. As another possible advantage of the formation of a deep trench 700 within shallow trench 600, element 1000 can have an improved breakthrough voltage. Advantageously, the width of shallow trench 600 can be matched to a possible misalignment of the mask for etching of deep trench 700.

The contacting of silicon substrate 100 through deep trench 700 (contact trench) is continued only after all elements are finished. For contacting polysilicon filling 750, oxide 580 in shallow trench 600 is removed above polysilicon 750 in a lithographic masked etching step. The etched oxide opening is now filled with a diffusion barrier 755, for example, made of a silicide, and with a metal 760, for example, tungsten. This process state is shown in FIG. 8.

FIG. 9 shows a schematic sectional view through a wafer with a power element 1000, which is formed in element region 400, and a contacting of silicon substrate 100. Silicon substrate 100 is thereby divided into several conductive substrate regions 110, 120, 130 by etched deep separation trenches 102, 103. Between conductive substrate regions 110, 120, 130 and below conductive substrate regions 110, 120, 130, a dielectric 101, for example, of silicon dioxide is formed, which isolates substrate regions 110, 120, 130 from one another and from the back of the wafer.

Conductive substrate regions 110, 120, 130 are, for example, formed of doped polycrystalline silicon, a silicide, or a metal. A substrate region 110 is thereby formed below power element 1000. Power element 1000 is isolated by the deep trench (700), filled with polysilicon 750, and by at least one other trench isolation 220 from neighboring elements (not shown in FIG. 9) by a dielectric 710, 220, particularly of silicon dioxide.

In the exemplary embodiment of FIG. 9, power element 1000 is an N-DMOS field-effect transistor 1000. This has an n-doped drain semiconductor region 1410, an N-well 1310, formed as a drift zone, a P-well 1320, formed as a body semiconductor region, an n-doped source semiconductor region 1420, and a p-doped body terminal semiconductor region 1430. Furthermore, N-DMOS field-effect transistor 1000 has a field oxide 1300 and a gate oxide 1500 with polysilicon gate electrode 1200 disposed thereon.

Drain semiconductor region 1410, gate electrode 1200, source semiconductor region 1420, and body terminal semiconductor region 1430 are each conductively connected to a metal trace 1110, 1120, 1130, and 1140. In the exemplary embodiment of FIG. 9, substrate region 110 is connected via polysilicon 750, diffusion barrier 755, metal 760, and trace 1110 to drain semiconductor region 1410, so that substrate region 110 substantially has the same potential as drain semiconductor region 1410. The wafer is protected by a boron-phosphorus-silicate glass 1900 from outside influences.

Alternatively to FIG. 9, substrate region 110 can also be connected to another element for controlling the potential of substrate region 110. Another possibility is to connect substrate region 110, for example, by means of a voltage divider, for example, of two capacitors to a fixed potential.

Proceeding from the process state shown in FIG. 4, FIGS. 10 and 11 show another exemplary embodiment, in which first a thin oxide 201 is deposited. After this, a thin wall layer 810 of silicon nitride (Si₃N₄) is deposited on the bottom region and on wall regions 701 of trench 700, which, for example, has a width of 0.8 μm, and a thin bottom layer 811 of silicon nitride (Si₃N₄) on bottom region 702 of trench 700. This process state is shown in FIG. 10.

Subsequently, thin oxide 201 and thin bottom layer 811 of silicon nitride (Si₃N₄) is removed by etching. Then, trench 700 is deep etched through buried insulation layer 200 to a conductive layer 104 of substrate 100. By this means, opening 270 is created in buried insulation layer 200, whereby in the opening, conductive layer 104 is exposed in trench 700.

Substrate 100 has a dielectric layer 105 and conductive layer 104, which is applied to dielectric layer 105. Conductive layer 104 in the exemplary embodiments of FIGS. 10 and 11 preferably has doped, polycrystalline silicon. In this case, other conductive materials can also be used for the conductive layer 104, but preferably the employed material can be oxidized to form a dielectric. Furthermore, the conductive material of the conductive layer is preferably suitable for bonding two wafers.

Preferably, the SOI structure is made with element region 400, buried insulation layer 200, and substrate 100 with conductive layer 104 and dielectric layer 105 in that a first wafer, forming substrate 100 and a second wafer are produced. The first wafer can be produced, for example, by conformal deposition of doped, polycrystalline silicon on a thick dielectric layer. The second wafer has insulation layer 200 and element region 400. After this, the first wafer is bonded with the side of conductive layer 104 to the side of insulation layer 200 of the second wafer.

Alternatively to FIG. 6, FIG. 12 shows an embodiment variant in which a conductive substrate region 146 is contacted by a conductor 751 with polycrystalline silicon 751. For this purpose, polycrystalline silicon 751 in the process state of FIG. 11 is introduced into trench 700, as a result of which a conductive connection to conductive substrate region 146 is created. Instead of polysilicon 751, a different conductive material can also be used, such as, for example, doped amorphous silicon or a silicide.

Alternatively, conductive layer 104 is separated into two conductive substrate regions 141 and 142 by an etched separation trench. According to FIG. 13, trench 700 is then filled with a dielectric 221 of silicon dioxide (SiO₂). The dielectric thereby also reaches into a gap between two substrate regions 142 and 141. As a result, the two substrate regions 142 and 141 are isolated from one another. If a trench structure is made according to FIG. 13 as a closed structure, for example, substrate region 142 can be isolated laterally in all directions by the closed trench structure. A trench structure filled with polycrystalline silicon 751 according to FIG. 12 can be used for contacting this substrate region 142, whereby in this case the substrate regions 142 and 146 are identical or border each other conductively. Advantageously, conductive layer 104 for patterning has a thickness that does not exceed 5 μm. If a thicker conductive layer is used, still lower resistances in the substrate regions 142, 141 can be realized.

This exemplary embodiment makes it possible that the patterning of conductive substrate regions 142 and 141 is made self-aligned to deep trench 700. A displacement of the two relative to one another is hereby avoided. If the trench is oriented to an element, an alignment of substrate region 142, 141 to the element is thereby also possible.

FIGS. 14, 15, and 16 show another embodiment variant for patterning a conductive layer 104 of substrate 100 through trench 700 and through opening 270 in buried insulation layer 200. In this case, first a photoresist is applied and patterned photolithographically. Patterned photoresist 910 forms a mask 910, which protects a first region of conductive layer 104 within trench 700 from an etching attack. However, a second region of conductive layer 104 of substrate 100 is not protected by the patterned photoresist 910. This process state is shown in FIG. 14.

In the second region, which is not protected by mask 910, conductive layer 104 is removed by etching. As a result, a separation trench 192 arises, which forms a gap between two conductive substrate regions 144 and 143, as is shown in FIG. 15. The exposed surface regions of two conductive substrate regions 144 and 143 of polycrystalline silicon are converted by a thermal oxidation to a first silicon dioxide region 148 and to a second silicon dioxide region 149. The first silicon dioxide region 148 grows on the sidewall of trench 700 at least partially under the buried insulator layer 200. Second silicon dioxide region 149 covers conductive substrate region 144 within trench 700. This process state is shown in FIG. 15.

Subsequently, thin wall layer 810 of silicon nitride (Si₃N₄) is removed. Moreover, second silicon dioxide region 149 is removed by isotopic plasma etching. For contacting of conductive substrate region 144, a conductor 752 with doped, polycrystalline silicon 752 is introduced into the trench structure, whereby the polysilicon filling 752 is conductively adjacent to conductive substrate region 144. This process state is shown in FIG. 16.

An especially space-saving formation can be achieved by said exemplary embodiment of FIG. 16, whereby in the same trench 700 both a patterning of a conductive layer 104 of substrate 100 in several conductive substrate regions 144 and 143 and isolation of substrate regions 143 and 144 from one another by a dielectric 148, as well as the contacting of a substrate region 144 by a conductor 752 introduced into trench 700, are synergetically formed.

Preferably, the conductive substrate regions are used as electrodes for power elements. Alternatively or in combination, for this purpose, a conductive substrate region can also be formed as a resistor or as a component of a capacitor.

A substrate region can also be formed as part of a screen. This is shown schematically in FIG. 17. The semiconductor array of FIG. 17 has a substrate 100 with three shown substrate regions 145, 144, and 143. The substrate regions 145, 144, 143 are isolated from one another by dielectric 148. The patterning of substrate regions 145, 144, 143 occurs in this case by means of separation trenches according to the exemplary embodiment of FIGS. 14 to 16. Polycrystalline silicon 752 is introduced into a deep trench, etched in element region 400, of a closed structure. Together with barrier material 755 and metal trace 760, this forms a conductor, which encompasses a circuit 2000 from several sides. If the conductor is connected to a potential, a screening of circuit 2000 can be realized. Here, circuit 2000 is screened laterally and vertically from spurious emissions by substrate region 144 and the conductor with polycrystalline silicon 752, barrier 755, and metal trace 760.

Circuit 2000 of FIG. 17 has, for example, an NMOS transistor with a P-well 2320, a p-body terminal region 2430, a source region 2420, a drain region 2500, a gate electrode 2201, a body metal terminal 2140, a source metal terminal 2130, a gate metal terminal 2200, and a drain metal terminal 2150. Circuit 2000 furthermore has an n-doped region 2310 for a PMOS transistor with a source region 2120, a drain region 2410, a gate electrode 2301, a source metal terminal 2120, and a gate metal terminal 2300. The drain metal terminal is connected to metal trace 760 of the conductor of the screen, so that the potential of the screen is controllable.

The invention is understandably not limited to the shown exemplary embodiments, but also comprises embodiment variants that are not shown. For example, substrate region 144 could only be contacted on one side. It is also possible to use a single-crystal conductive layer 104 of substrate 100. The invention is also not limited to the elements 1000 and circuit 2000 shown in FIGS. 9 and 17, but protects, for example, every semiconductor array with any elements that make use of the patterning of a buried conductive layer of an SOI substrate within a trench 700.

### LIST OF REFERENCE CHARACTERS

100 Substrate
101 Dielectric, silicon dioxide
102, 103 Separation trenches filled with dielectric
104 Polycrystalline silicon layer of the substrate
105 Dielectric layer of the substrate
110, 120, 130, 141, Conductive substrate region
142, 143, 144, 145,
146
148, 149 Dielectric, silicon dioxide
192 Separation trench in the polycrystalline silicon layer of the substrate
200 Buried insulation layer, SiO₂
210 Silicon dioxide layer
220 Deep trench filled with dielectric
221 Dielectric, silicon dioxide
270 Opening in the buried insulation layer
300 Single-crystal silicon crystal
400 Element region
410 Region with crystal imperfections
510 First oxide layer
520 Polysilicon layer
530 Second oxide layer
550, 550′ Oxide layer
580, 580′ Dielectric, silicon dioxide
600 Shallow, etched trench
700 Deep trench, etched
701 Wall of the deep trench
702 Bottom of the deep trench
710 Insulation material, silicon dioxide
720 Insulation material, silicon dioxide
750, 751, 752 Doped polysilicon filling
755 Diffusion barrier, silicide
760 Metal, tungsten, aluminum
800, 810, 811 Hard mask, Si₃N₄
900, 910 Resist, photoresist masking
1000 Element, N-DMOS field-effect transistor
1110, 1120, Metallization, trace
1130, 1140, 2140,
2130, 2200, 2150,
2120, 2300
1200, 2201, 2301 Gate electrode, polycrystalline silicon
1300 Field oxide
1310, 2310 N-well, drift zone
1320, 2320 P-well, body
1410, 2500, 2410 Drain semiconductor region
1420, 2420, 2330 Source semiconductor region
1430, 2430 Body terminal semiconductor region
1500 Gate oxide
1900, 2900 Boron-phosphorus-silicate glass
B Dopant (boron) of an implantation

1. Method for manufacturing a semiconductor array, wherein a conductive substrate an element regions, and an insulation layer, isolating the element region from the conductive substrate, are formed, a trench is etched in the element region as far as the insulation layer, the trench is etched further in the insulation layer as far as the conductive substrate, and the conductive substrate is partially etched to form conductive substrate regions, isolated from one another.

2. Method according to claim 1, wherein the conductive substrate is etched at least partially within the trench in order to form conductive substrate regions, isolated from one another.

3. Method according to claim 2, wherein a conductive layer of the substrate is patterned by etching to form the isolation of the substrate regions and an exposed region of the conductive layer is thermally oxidized to form an insulating dielectric.

4. Method according to claim 3, wherein for patterning a mask is formed which protects a first region of the conductive layer within the trench from the etching attack, and wherein a second region, not protected by the mask, of the conductive layer is removed by the etching.

5. Method according to claim 1, wherein to form the insulation of the substrate regions, a conductive layer of the substrate is removed at least partially within the trench by the etching, and wherein within the trench a dielectric is deposited between the formed substrate regions.

6. Method according to any claim 1, wherein an electrical conductor is introduced into the trench or into another trench and conductively connected to a substrate region of the substrate regions isolated from one another.

7. Method according to claim 1, wherein the substrate is formed with a dielectric layer and with a conductive layer.

8. Method according to claim 1, wherein a shallow recess is etched in a surface of the element region, wherein the trench is etched within the shallow recess in the element region, and wherein the walls of the trench are formed with an insulation material.

9. Method according to claim 8, wherein the shallow recess is filled with dielectric, and wherein a dopant (B) is introduced for a semiconductor region of the at least one element, whereby the dielectric in the shallow recess serves as masking to make the semiconductor region of the at least one element self-aligned to the recess in the element region.

10. Method according to either claim 8, wherein to form the insulation material a silicon region, adjacent to the trench, of the element region is oxidized.

11. Method according to claim 1, wherein the conductive substrate to form conductive substrate regions, isolated from one another, is etched from the substrate side facing away from the trench, wherein the walls of the trench are formed with an insulation material, and wherein an electrical conductor is introduced into the trench and connected conductively to at least one substrate region of the conductive substrate regions.

12. Semiconductor array, with an element region, with a conductive substrate, with a buried insulation layer, which isolates the element region from the conductive substrate, with at least one trench, which is filled with an insulation material and which isolates at least one element in the element region from other elements in the element region, with an electrical conductor, which is connected conductively to the conductive substrate, wherein the electrical conductor is disposed within the trench isolated by the insulation material, and wherein the conductive substrate has substrate regions, which are divided by a number of etched trenches,
whereby the trenches are filled with a dielectric for isolation.

13. Semiconductor element according to claim 12, wherein several substrate regions, isolated from one another, are each connected conductively to at least one conductor disposed in one trench each.

14. Semiconductor array according to claim 12, wherein at least one of the substrate regions is formed below the element and wherein the element is a lateral DMOS field-effect transistor.

15. Semiconductor array according to claim 12, wherein a conductor and one substrate region of the substrate regions surround the at least one element at least partially and are together formed as a screen.

16. Semiconductor array according to claim 12, wherein within the trench a dielectric is disposed for isolating the substrate regions from one another.

17. Semiconductor array according to claim 12, wherein the trench is formed within a recess in a surface.

18. Semiconductor array according to claim 12, wherein a semiconductor region of the at least one element is formed self-aligned to the recess in the element region.

19. Circuit with a semiconductor array according to claim 12, which has means for applying a constant or controllable potential to the electrical conductor, whereby at least one electrical property of the at least one element depends on the constant or controllable potential.

20. Use of a conductive substrate region and a conductor, connected conductively to the substrate region, for multisided screening of an element, which is disposed on top of the conductive substrate region and is isolated dielectrically from the substrate region.
